(19) United States
(12) Patent Application Publication
(10) Pub. No.: US 2019/0086478 A1
(43) Pub. Date: Mar. 21, 2019

(54) APPARATUS AND METHOD FOR ESTIMATING STATE OF BATTERY

(71) Applicant: Samsung Electronics Co., Ltd., Suwon-si (KR)

(72) Inventors: SangDo PARK, Seoul (KR); Kaeweon YOU, Hwaseong-si (KR); Young Hun SUNG, Hwaseong-si (KR)

(73) Assignee: Samsung Electronics Co., Ltd., Suwon-si (KR)

(21) Appl. No.: 15/964,712

(22) Filed: Apr. 27, 2018

(30) Foreign Application Priority Data
Sep. 20, 2017 (KR) 10-2017-0121023

(51) Int. Cl. G01R 31/36

(52) U.S. Cl. CPC G01R 31/3651; G01R 31/3679

(57) ABSTRACT

A battery state estimation apparatus and method are provided. The processor implemented battery state estimation apparatus estimates attention data indicating data suitable for a state estimation from battery data, and estimates battery state information based on the battery data and the attention data.

### CROSS-REFERENCE TO RELATED APPLICATIONS

This application claims the benefit under 35 USC § 119(a) of Korean Patent Application No. 10-2017-0121023, filed on Sep. 20, 2017, in the Korean Intellectual Property Office, the entire disclosure of which is incorporated herein by reference for all purposes.

### BACKGROUND

### 1. Field

The following description relates to a technology of estimating a state of a battery.

### 2. Description of Related Art

Many electronic devices include batteries, for example, secondary batteries, that are repeatedly charged during operation of the electronic devices. As the number of times a secondary battery is discharged and recharged increases, the capacity of the secondary battery to hold a charge gradually decreases. With each charging cycle, the lifespan of a battery of an electronic device decreases. Due to the decrement in the lifespan of the battery, the initial battery capacity may no longer be attainable after a large number of charging and discharging cycles. With a continual reduction in the capacity of the battery, the power, the operating time and/or the stability of the electronic device may become compromised. Accordingly, the battery typically needs to be replaced with a replacement battery to improve the power, the operating time and/or the stability of the electronic device over time.

For example, to determine an expected time to replace the battery, a state of health (SOH) of the battery may be estimated.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a processor implemented method of estimating battery state information includes acquiring input data corresponding to battery data collected from a battery, estimating attention data from the input data based on an attention model, and estimating battery state information from the input data and the attention data based on a battery model.

The battery may be partially charged or partially discharged.

The estimating of the battery state information may be performed while the battery is being used as a power source of an electronic apparatus.

The battery state information may be a state of health (SOH) of the battery, and the method further indicates the SOH.

The acquiring of the input data may include generating the input data by preprocessing the collected battery data.

The acquiring of the input data may include generating the input data by dividing the battery data based on a time.

The estimating of the battery state information may include estimating a lifespan of the battery from the input data and the attention data based on the battery model.

The acquiring of the input data may include collecting the battery data including any one or any combination of a voltage signal output from the battery, a current signal output from the battery and a temperature of the battery.

The acquiring of the input data may include collecting the battery data corresponding to at least a portion of a charging cycle of the battery or at least a portion of a discharging cycle of the battery.

The estimating of the battery state information may include selecting at least a portion of the input data based on the attention data, and estimating the battery state information from the selected portion of the input data and the attention data based on the battery model.

The acquiring of the input data may include generating the input data based on statistical values of the battery data.

The estimating of the battery state information may include generating integrated data by merging the attention data and the input data, and estimating the battery state information from the integrated data based on the battery model.

The estimating of the battery state information may include estimating feature data from the input data and the attention data based on the battery model, and calculating the battery state information from the feature data based on a regression model.

In another general aspect, a battery state estimation apparatus includes a data acquirer configured to collect battery data from a battery, and a processor configured to acquire input data corresponding to the battery data, to estimate attention data from the input data based on an attention model, and to estimate battery state information from the input data and the attention data based on a battery model.

The processor may be further configured to generate the input data by preprocessing the collected battery data.

The processor may be further configured to generate the input data by dividing the battery data based on a time.

The processor may be further configured to estimate a lifespan of the battery from the input data and the attention data based on the battery model.

The data acquirer may be further configured to collect the battery data including any one or any combination of a voltage signal output from the battery, a current signal output from the battery and a temperature of the battery.

The data acquirer may be further configured to collect the battery data corresponding to at least a portion of a charging cycle of the battery or at least a portion of a discharging cycle of the battery.

The processor may be further configured to select at least a portion of the input data based on the attention data, and to estimate the battery state information from the selected portion of the input data and the attention data based on the battery model.

The processor may be further configured to generate the input data based on statistical values of the battery data.

The processor may be further configured to generate integrated data by merging the attention data and the input data and to estimate the battery state information from the integrated data based on the battery model.

Other features and aspects will be apparent from the following detailed description, the drawings, and the claims.

### BRIEF DESCRIPTION OF THE DRAWINGS

FIG. 1 is a diagram illustrating an example of a battery state estimation system.

FIGS. 2 and 3 are block diagrams illustrating examples of a configuration of a battery state estimation apparatus.

FIGS. 4, 5 and 6 are diagrams illustrating examples of a process of estimating battery state information using a battery model and an attention model.

FIGS. 7 and 8 are flowcharts illustrating examples of a battery state estimation method.

FIG. 9 illustrates an example of a vehicle.

Throughout the drawings and the detailed description, unless otherwise described or provided, the same drawing reference numerals will be understood to refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The following structural or functional descriptions of examples disclosed in the present disclosure are merely intended for the purpose of describing the examples and the examples may be implemented in various forms. The examples are not meant to be limited, but it is intended that various modifications, equivalents, and alternatives are also covered within the scope of the claims.

Although terms of “first” or “second” are used to explain various components, the components are not limited to the terms. These terms should be used only to distinguish one component from another component. For example, a “first” component may be referred to as a “second” component, or similarly, and the “second” component may be referred to as the “first” component within the scope of the right according to the concept of the present disclosure.

As used herein, the singular forms are intended to include the plural forms as well, unless the context clearly indicates otherwise. It should be further understood that the terms “comprises” and/or “comprising,” when used in this specification, specify the presence of stated features, integers, steps, operations, elements, components or a combination thereof, but do not preclude the presence or addition of one or more other features, integers, steps, operations, elements, components, and/or groups thereof.

Unless otherwise defined herein, all terms used herein including technical or scientific terms have the same meanings as those generally understood. Terms defined in dictionaries generally used should be construed to have meanings matching with contextual meanings in the related art and are not to be construed as an ideal or excessively formal meaning unless otherwise defined herein.

Hereinafter, examples will be described in detail with reference to the accompanying drawings, and like reference numerals in the drawings refer to like elements throughout.

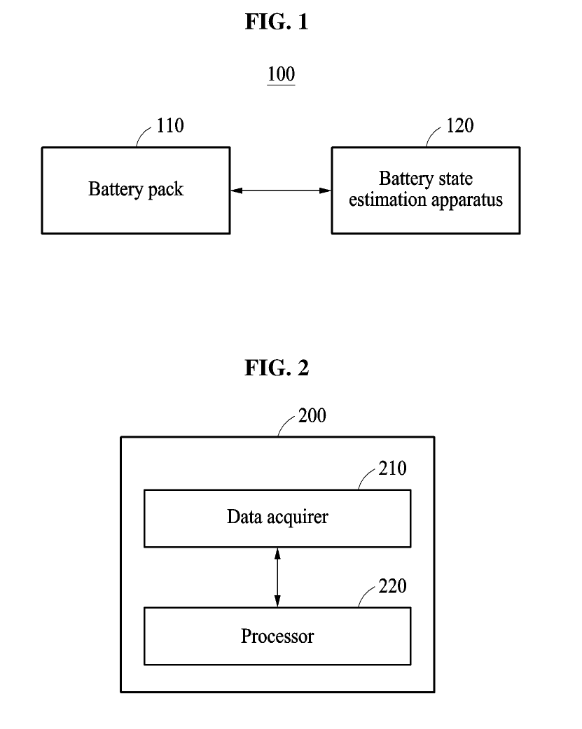

FIG. 1 illustrates an example of a battery state estimation system 100.

The battery state estimation system 100 includes a battery pack 110 and a battery state estimation apparatus 120.

The battery pack 110 is at least one battery including a plurality of battery cells. In the battery pack 110, battery cells are rechargeable and used to supply power of the charged battery cells to an apparatus. In the following description, the battery pack 110 is referred to as a “battery.”

The apparatus is an electrical apparatus including, or configured to include, a battery, and includes, for example, an electric vehicle (EV), a hybrid vehicle, or an energy storage system (ESS).

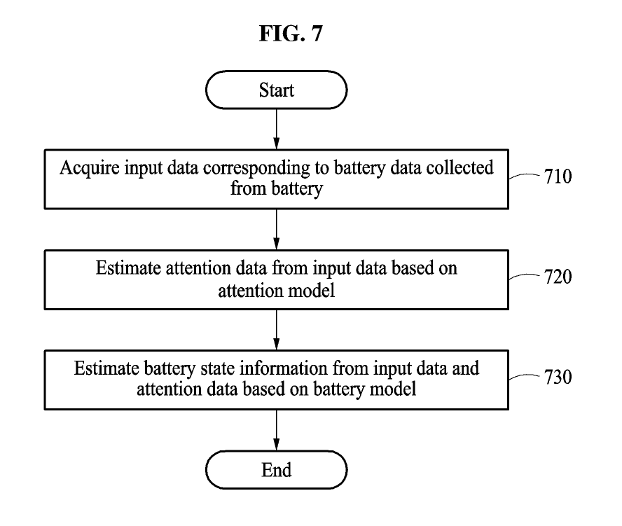

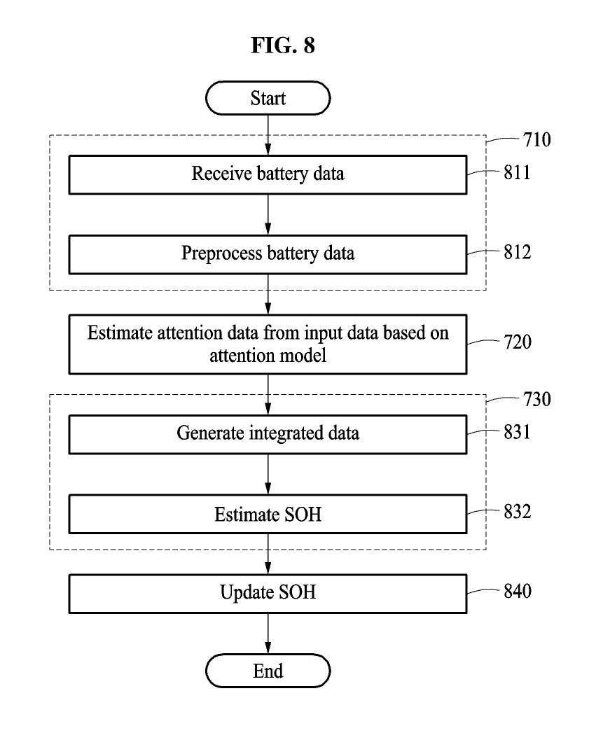

The battery state estimation apparatus 120 estimates a state of the battery pack 110. The battery state estimation apparatus 120 executes software instructions in which an algorithm to perform a method (for example, battery state estimation methods of FIGS. 7 and 8) is implemented, or includes a processor chip in which the algorithm is implemented, e.g., with or without such instructions. For example, the battery state estimation apparatus 120 is mounted in an electrical apparatus, for example, an EV.

In the following description, battery state information includes, for example, information associated with the lifespan of a battery. The information associated with the lifespan of the battery includes, for example, a state of health (SOH), a state of charge (SOC) or a remaining useful life of the battery. For example, the SOH is represented by a ratio of a current capacity of the battery to an initial capacity of the battery; however, there is no limitation thereto as the SOH may be represented using various schemes. In the following description, an SOH of a battery is provided as an example of battery state information, however, there is no limitation thereto.

The battery state estimation apparatus 120 is included in an EV in which the battery pack 110 having a plurality of batteries is mounted. Also, the battery state estimation apparatus 120 is included in a plug-in hybrid EV (PHEV) or a hybrid EV (HEV).

Unlike a current integration technique that requires fully charging or fully discharging of a battery, the battery state estimation apparatus 120 does not require a battery to be fully charged or discharged to determine the SOH or state of the battery. Because fully charging or discharging the battery is not required, the battery state estimation apparatus 120 estimates the battery state information without a reduction in a lifespan of a battery; thereby, providing an improvement over typical methods of estimating a battery's life. Also, the current integration techniques need to use an electrochemical impedance spectroscopy (EIS) measurement at a reference temperature, a reference SOC and a reference pressure, whereas the battery state estimation apparatus 120 freely estimates a battery state information without such constraint as temperature and pressure are not required; thereby, providing an improvement over current methods of estimating a battery's life.

Typically, an EIS measurement is used to measure a state of a battery that is at rest for at least 30 minutes, whereas the battery state estimation apparatus 120 estimates battery state information even when the battery is being used. Thus, the battery state estimation apparatus 120 determines the lifespan of the battery even when an EV is operating; thereby, providing an improvement over current methods of estimating a battery's life. Also, EIS equipment is bulky and heavy, however, the battery state estimation apparatus 120 is relatively compact in size, and accordingly is included in, for example, an EV.

In addition, a state estimation that uses an electrical circuit model (ECM) or an electrochemical-thermal (ECT) model requires discharging of a predetermined amount of current. For an EV, the accuracy of the state estimation that uses an ECM and/or an ECT model is reduced.

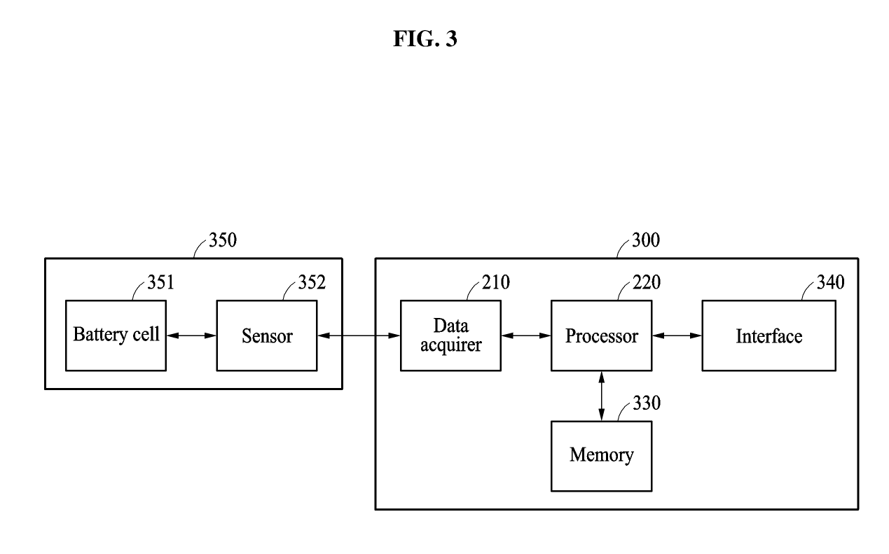

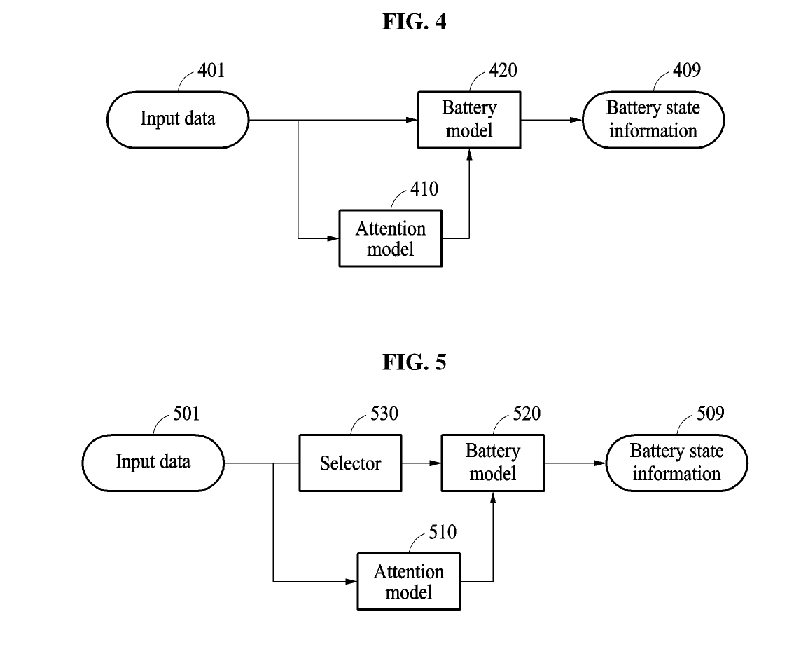

FIGS. 2 and 3 illustrate examples of a configuration of a battery state estimation apparatus.

FIG. 2 illustrates an example of a configuration of a battery state estimation apparatus 200. The battery state estimation apparatus 200 of FIG. 2 includes a data acquirer 210 and a processor 220.

The data acquirer 210 collects battery data from a battery. For example, the data acquirer 210 collects a voltage signal output from the battery, a current signal output from the battery and/or a temperature of the battery. During charging or discharging cycles of the battery, the data acquirer 210 collects voltage signals, current signals and temperatures of the battery at regular predetermined time intervals. Examples include the time intervals being set in hours, minutes or seconds, based on a design, however, there is no limitation thereto. Also, the data acquirer 210 may collect the battery data in a form of discrete data as described above, however, there is no limitation thereto. For example, the battery data is collected in a form of continuous data.

The data acquirer 210 collects battery data corresponding to at least a portion of a charging cycle of the battery and/or at least a portion of a discharging cycle of the battery. For example, when a current capacity of the battery is x % in which x is a real number that is greater than or equal to “0” and less than “100”, the data acquirer 210 collects battery data corresponding to a portion of a cycle in which the battery is charged until the capacity changes from x % to y % in which y is a real number that is greater than or equal to “x” and equal to or less than “100”. Also, the data acquirer 210 collects battery data corresponding to a portion of a cycle in which the battery is discharged until the capacity changes from x % to z % in which z is a real number that is greater than or equal to “0” and less than “x.”

In the following description, a cycle in which a battery with a minimum capacity (for example, 0%) is charged to a maximum capacity (for example, 100%) is referred to as a “fully charging cycle.” Also, a cycle in which a battery with the maximum capacity is discharged until the battery reaches the minimum capacity is referred to as a “fully discharging cycle.”

The processor 220 acquires input data corresponding to the battery data, estimates attention data from the input data based on an attention model, and estimates battery state information from the input data and the attention data based on a battery model. The input data is data that is generated by preprocessing and converting the battery data so that the battery data is input to the battery model and a degradation model. The attention data is data that indicates information suitable for estimation of a state of the battery in the input data.

The battery model is a model used to output a degree of degradation in a state of a battery (for example, a battery lifespan or a malfunction) due to an arbitrary factor. The attention model is a model used to output information suitable for estimation of the state of the battery among information associated with the battery. For example, the attention model and the battery model may be models applied to or resulting from machine learning. The attention model and the battery model may each be respectfully defined by, for example, parameters of a machine learning structure. For example, when a neural network is used as the machine learning structure, the parameters of the attention model and the battery model may be connection weights between nodes in each neural network.

The battery model may include trained parameters in a machine learning structure (for example, a neural network), which after substantial computational training and parameter adjustments are trained to output reference state information corresponding to reference battery information based on the reference battery information through a given machine learning structure. Training data used to the battery model includes pairings of the reference state information and the reference battery information. The reference state information includes, for example, state information (for example, a life) of a battery with predetermined reference battery information in an existing profile.

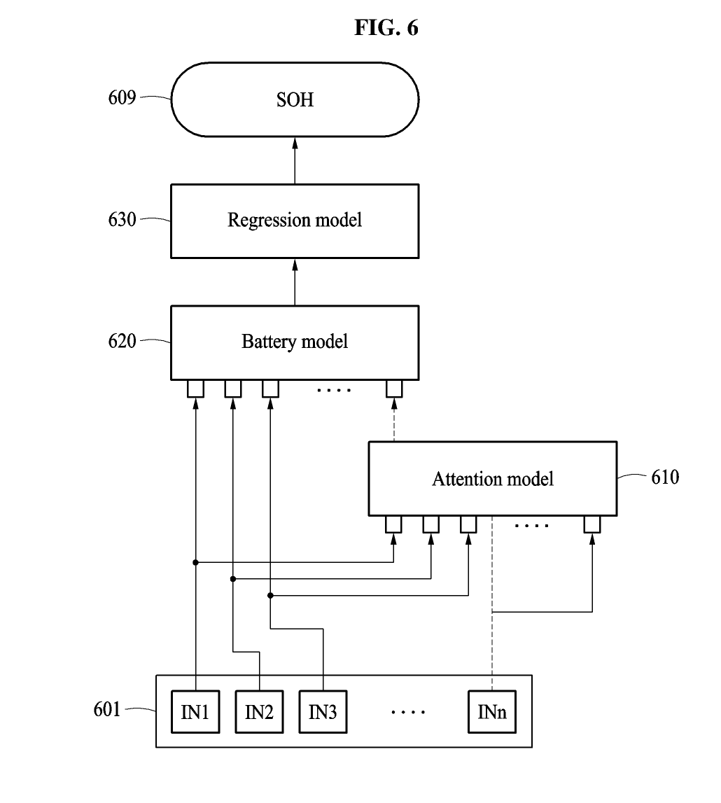

The attention model may also include trained parameters of a machine learning structure (for example, a neural network), which after substantial computational training and parameter adjustments are trained to output reference attention information corresponding to reference battery information based on the reference battery information, in a given machine learning structure. The attention model operates with the battery model, and is trained together with the battery model in response to training of the battery model. Examples of the attention model and the battery model will be further described below with reference to FIGS. 4, 5 and 6.

The processor 220 estimates the battery state information based on battery data corresponding to a portion of a cycle, using the attention model and the battery model. The data acquirer 210 monitors a portion of the fully charging cycle or a portion of the fully discharging cycle instead of needing to monitor the entire fully charging cycle and the entire fully discharging cycle. Thus, the processor 220 estimates the battery state information based on data associated with charging or discharging for a relatively short period of time.

FIG. 3 illustrates an example of a configuration of each of a battery pack 350 and a battery state estimation apparatus 300.

Referring to FIG. 3, the battery state estimation apparatus 300 includes a memory 330 and an interface 340 in addition to the data acquirer 210 and the processor 220 of FIG. 2.

The data acquirer 210 receives battery data from a sensor 352 installed in the battery pack 350. For example, the data acquirer 210 is wiredly and/or wirelessly connected to the sensor 352 to receive the battery data from the sensor 352, however, there is no limitation thereto.

The processor 220 operates as described above in FIG. 2. In addition, the processor 220 generates input data by preprocessing collected battery data. For example, the processor 220 removes noise from the battery data, to generate the input data. Also, the processor 220 divides or parses the battery data based on a time, to generate the input data. An example of dividing battery data based on a time will be described below with reference to FIG. 6.

Also, the processor 220 calculates attention data by utilizing the input data as described above. The processor 220 outputs, as attention data, information indicating a sensitivity and an importance of at least a portion of the input data in estimating of a state of a battery, based on the attention model.

The processor 220 selects, based on the attention data, data that is to be used to estimate the state of the battery. For example, the processor 220 selects at least a portion of the input data, based on the attention data. The processor 220 selects a portion of the input data, based on the attention data, and excludes the remaining data from an operation. The processor 220 selects a portion of the input data corresponding to an attention value that exceeds a threshold among attention values included in the attention data.

The processor 220 applies both the attention data and the battery data to the battery model and estimates battery state information. For example, the processor 220 estimates the battery state information from the attention data and at least a portion of the input data, based on the battery model. The processor 220 applies the attention data and a selected portion of the input data to the battery model and estimates the battery state information, and thus it is possible to reduce a calculation amount and power consumption.

Also, the processor 220 generates integrated data by merging the attention data and the input data, and estimates the battery state information from the integrated data based on the battery model. For example, the processor 220 merges the attention data and the input data, to generate integrated data in a single vector form, which is input to the battery model.

The memory 330 stores the battery data, the input data, the attention data, the battery model and the attention model that are described above. Also, the memory 330 stores temporary data that is used for an operation using the battery model and the attention model. The memory 330 accumulates and stores the estimated battery state information, or temporarily stores the estimated battery state information.

The interface 340 indicates the estimated battery state information, e.g., either explicitly or implicitly. For example, the interface 340 visually outputs (for example, displays) or acoustically outputs (for example, outputs in a form of audio) the estimated battery state information, or implicitly includes the estimated battery state information through operations.

The battery pack 350 includes a battery cell 351 and the sensor 352.

The battery cell 351 stores power that is to be supplied to an apparatus. Although a single battery cell, that is, the battery cell 351 is shown in FIG. 3, there is no limitation thereto. For example, a plurality of battery cells are provided.

The sensor 352 senses information associated with the battery cell 351, and generates the battery data. For example, the sensor 352 senses a temperature of the battery cell 351, and a voltage signal and a current signal that are output from the battery cell 351. The sensor 352 transmits the battery data to the battery state estimation apparatus 300.

FIGS. 4 through 6 illustrate examples of a process of estimating battery state information using a battery model and an attention model.

FIG. 4 illustrates an example of a process by which a processor of a battery state estimation apparatus estimates battery state information 409 from input data 401 based on a battery model 420 and an attention model 410.

For example, the processor calculates attention data from the input data 401 based on the attention model 410. As described above, the attention data is a data indicating information suitable for use in estimating a state of a battery in the input data 401. The input data 401 is data generated by preprocessing battery data. The processor calculates the battery state information 409 from the attention data and the input data 401 based on the battery model 420. The processor applies both the input data 401 and the attention data to the battery model 420, and calculates the battery state information 409 focused on important information from the input data 401.

FIG. 5 illustrates an example of a process by which a processor of a battery state estimation apparatus estimates a state of a battery by selecting important information from input data 501 using a selector 530.

For example, the processor calculates attention data from the input data 501 based on an attention model 510. The processor selects at least a portion of the input data 501 using the attention data and the selector 530. For example, the processor selects a portion of the input data 501 corresponding to an attention value that exceeds a threshold among attention values included in the attention data. The processor calculates battery state information 509 from the attention data and the selected portion of the input data 501 based on a battery model 520.

FIG. 6 illustrates an example of a machine learning structure (for example, a neural network) in which a processor of a battery state estimation apparatus estimates battery state information 609 from input data 601 based on an attention model 610, a battery model 620 and a regression model 630.

The input data 601 is data generated from battery data, as described above. For example, when a data acquirer of a battery state estimation apparatus collects battery data during a portion of a cycle (for example, a charging cycle or a discharging cycle), the processor divides or parses battery data corresponding to the portion of the cycle into “n” pieces in which n is an integer greater than or equal to “1.” In FIG. 6, IN1 through INn denote “n” pieces of vector data obtained by dividing the battery data. Time intervals for the “n” pieces of vector data partially overlap each other. Each of the “n” pieces of vector data includes “m” values obtained by sampling a current signal at regular time intervals, “m” values obtained by sampling a voltage signal at regular time intervals, and “m” values obtained by sampling a temperature signal at regular time intervals.

For example, i-th vector data is represented as INi=[Viₜ_{_}₁, Viₜ_{_}₂, . . . , Viₜ_{_}ₘ, Iiₜ_{_}₁, Iiₜ_{_}₂, . . . , Iiₜ_{_}ₘ, Tiₜ_{_}₁, Tiₜ_{_}₂, . . . , Tiₜ_{_}ₘ]. In the above equation, i is an integer greater than or equal to “1” and less than or equal to “n”, m is an integer greater than or equal to “1”, t_x denotes an x-th point in time in vector data, and x is an integer greater than or equal to “1” and less than or equal to “m.” For example, Viₜ_{_}ₘ denotes a voltage value at a t_m-th point in time in the i-th vector data of battery data corresponding to a portion of a cycle, Iiₜ_{_}ₘ denotes a current value at the t_m-th point in time in the i-th vector data of the battery data, and Tiₜ_{_}ₘ denotes a temperature value at the t_m-th point in time in the i-th vector data of the battery data.

However, a generation of the input data 601 is not limited to the above description. In one example, the processor generates the input data 601 based on statistical values of the battery data. The processor divides the battery data into “n” pieces of vector data (for example, vector data IN1 through INn), and represents each of the “n” pieces of vector data as INi=[Vi_{M}, Ii_{M}, Ti_{M}]. Vi_{M} denotes a median value of voltage values included in i-th vector data, Ii_{M} denotes a median value of current values included in the i-th vector data, and Ti_{M} denotes a median value of temperature values included in the i-th vector data. However, the statistical values are not limited to the median values, and accordingly various statistical values, for example, an average value, a maximum value or a minimum value, are applied.

The processor calculates attention data from the generated input data 601 based on the attention model 610. For example, the attention data indicates a level at which a state of a battery is associated with vector data of the input data.

Also, the processor estimates feature data from the input data 601 and the attention data based on the battery model 620. The feature data represents a feature vector extracted from the input data 601. The feature vector is a set of values obtained by abstracting the input data 601.

The processor calculates the battery state information 609 from the feature data based on the regression model 630. The regression model 630 is a model trained to output the battery state information 609 based on the feature data. In an example, the regression model 630 includes a logistic regression, and outputs the battery state information 609 in a form of a continuous value instead of a discrete value. As shown in FIG. 6, the processor estimates a lifespan (for example, an SOH) of the battery from the input data 601 and the attention data based on the battery model 620.

Examples of a battery state estimation method are described with reference to FIGS. 7 and 8.

FIG. 7 is a flowchart illustrating an example of a battery state estimation method.

Referring to FIG. 7, in operation 710, a processor of a battery state estimation apparatus acquires input data corresponding to battery data collected from a battery. For example, as described above, the processor receives the collected battery data from a data acquirer of a battery state estimation apparatus.

In operation 720, the processor estimates attention data from the input data based on an attention model. For example, the processor loads a pre-trained attention model from a memory, such as by loading pre-trained parameters of the attention model when the attention model is a neural network or neural network portion of a battery estimation model that also includes other neural network portions corresponding to the battery model and/or the regression model. The processor inputs the input data to the loaded attention model to thereby implement the attention model to generate the attention data.

In operation 730, the processor estimates battery state information from the input data and the attention data based on a battery model. For example, the processor loads a pre-trained battery model from the memory, such as by loading pre-trained parameters of the battery model when the battery model is a neural network or the other neural network portion of the battery estimation model. The processor inputs the input data and the attention data to the loaded battery model to thereby implement the battery model to generate the battery state information. The battery state information may then be indicated, e.g., indicated to a user of the EV.

FIG. 8 is a flowchart illustrating an example of the battery state estimation method of FIG. 7.

Referring to FIG. 8, in operation 710, the processor generates input data. In operation 811, the processor receives battery data from the data acquirer. For example, the processor receives a voltage signal output from a battery, a current signal output from the battery or a temperature of the battery. In operation 812, the processor preprocesses the received battery data. For example, the processor eliminates an error from the battery data or applies filtering, to generate the input data.

In operation 720, the processor estimates the attention data from the input data based on the attention model, as described above with reference to FIG. 7. The processor inputs the input data to the attention model, to generate attention data that indicates a level at which the input data is associated with battery state information. For example, the processor performs grouping or labeling of input data that is associated with a final output (for example, battery state information) using the attention model. The processor estimates a lifespan of the battery based on a change in a voltage value of the battery and a change in a current value of the battery due to a change in state information (for example, a life) of the battery, using the attention model. For example, the attention model may have been trained based on pre-profiled reference battery information and pre-profiled reference battery state information for the objective to output attention data indicating data suitable for estimation, e.g., in conjunction with the training of battery model, of the lifespan of the battery among the input data. Thus, the attention model may perform a focusing or emphasizing of data suitable for estimation by the battery model, which may thereby increase accuracy and enable such battery state estimation under additional circumstances that may not have been available in typical battery state estimation approaches.

In operation 730, the processor estimates the battery state information. In operation 831, the processor generates integrated data. For example, the processor merges the attention data and the input data into integrated data that is in a form of a single vector. In operation 832, the processor estimates an SOH. For example, the processor inputs the integrated data to the battery model so that feature data is output. The processor inputs the feature data to a regression model, and calculates the SOH, that is, final battery state information.

In operation 840, the processor updates the SOH. For example, an interface updates the SOH calculated by the processor and provides or indicates the updated SOH to a user.

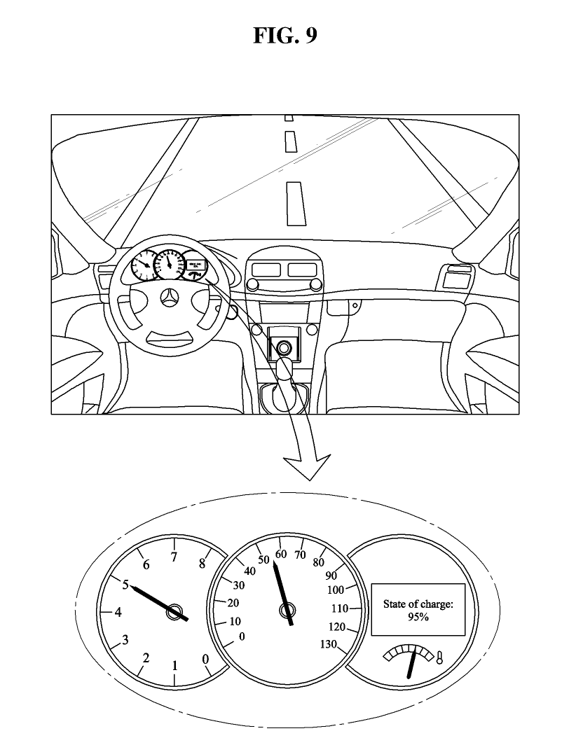

The battery state estimation apparatus 120 transmits the battery state information an ECU or a VCU of the herein example EV, for example. As illustrated in FIG. 9, the ECU or the VCU may indicate the battery state information of the battery on a display of a vehicle. The display includes, for example, a dashboard and/or a head-up display (HUD).

According to examples, a battery state estimation apparatus may automatically extract information suitable for estimation of a state of a battery from battery data using an attention model. The battery state estimation apparatus estimates the state of the battery with a high accuracy based on information determined to be suitable for the estimation of the state of the battery.

Also, the battery state estimation apparatus may extract optimal information from the battery data using the attention model, and thus it is possible to prevent an unnecessary state estimation. For example, in a state in which a voltage and current of the battery irregularly fluctuate, a data acquirer of the battery state estimation apparatus senses battery data in a transition state. Due to the battery data in the transition state, an error occurs. Thus, the battery state estimation apparatus may correct or eliminate an error in input data, using the attention model.

Furthermore, the battery state estimation apparatus may determine, using the attention model in advance, whether estimation of a state based on battery data that is currently collected is possible. When the estimation of the state is determined to be impossible based on the result of the battery state estimation, the battery state estimation apparatus may prevent an unnecessary operation.

The battery state estimation system 100, the battery state estimation apparatus 120, the data acquirer 210, the sensor 352, the interface 340, the battery state estimation apparatuses 200 and 300, the battery pack 350 and other components described herein with respect to FIGS. 1 through 3 are implemented by hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 7 and 8 that perform the operations described in this application are performed by computing hardware, for example, by one or more processors or computers, implemented as described above executing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control a processor or computer to implement the hardware components and perform the methods as described above are written as computer programs, code segments, instructions or any combination thereof, for individually or collectively instructing or configuring the processor or computer to operate as a machine or special-purpose computer to perform the operations performed by the hardware components and the methods as described above. In one example, the instructions or software include machine code that is directly executed by the processor or computer, such as machine code produced by a compiler. In another example, the instructions or software include higher-level code that is executed by the processor or computer using an interpreter. The instructions or software may be written using any programming language based on the block diagrams and the flow charts illustrated in the drawings and the corresponding descriptions in the specification, which disclose algorithms for performing the operations that are performed by the hardware components and the methods as described above.

The instructions or software to control a processor or computer to implement the hardware components and perform the methods as described above, and any associated data, data files, and data structures, are recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and providing the instructions or software and any associated data, data files, and data structures to a processor or computer so that the processor or computer can execute the instructions.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A processor implemented method of estimating battery state information, comprising:
acquiring input data corresponding to battery data collected from a battery;
estimating attention data from the input data based on an attention model; and
estimating battery state information from the input data and the attention data based on a battery model.

2. The method of claim 1, wherein the acquiring of the input data comprises generating the input data by preprocessing the collected battery data.

3. The method of claim 1, wherein the acquiring of the input data comprises generating the input data by dividing the battery data based on a time.

4. The method of claim 1, wherein the estimating of the battery state information comprises estimating a lifespan of the battery from the input data and the attention data based on the battery model.

5. The method of claim 1, wherein the acquiring of the input data comprises collecting the battery data comprising any one or any combination of a voltage signal output from the battery, a current signal output from the battery and a temperature of the battery.

6. The method of claim 1, wherein the acquiring of the input data comprises collecting the battery data corresponding to at least a portion of a charging cycle of the battery or at least a portion of a discharging cycle of the battery.

7. The method of claim 1, wherein the estimating of the battery state information comprises:
selecting one or more select portions of the input data based on the attention data; and
estimating the battery state information from the selected one or more select portions of the input data and the attention data based on the battery model.

8. The method of claim 1, wherein the acquiring of the input data comprises generating the input data based on statistical values of the battery data.

9. The method of claim 1, wherein the estimating of the battery state information comprises:
generating integrated data by merging the attention data and the input data; and
estimating the battery state information from the integrated data based on the battery model.

10. The method of claim 1, wherein the estimating of the battery state information comprises:
estimating feature data from the input data and the attention data based on the battery model; and
calculating the battery state information from the feature data based on a regression model.

11. A non-transitory computer-readable storage medium storing instructions that, when executed by a processor, cause the processor to perform the method of claim 1.

12. An apparatus for estimating battery state information, comprising:
a data acquirer configured to collect battery data from a battery; and
a processor configured to:
acquire input data corresponding to the battery data;
estimate attention data from the input data based on an attention model; and
estimate battery state information from the input data and the attention data based on a battery model.

13. The apparatus of claim 12, wherein the processor is further configured to generate the input data by preprocessing the collected battery data.

14. The apparatus of claim 12, wherein the processor is further configured to generate the input data by dividing the battery data based on a time.

15. The apparatus of claim 12, wherein the processor is further configured to estimate a lifespan of the battery from the input data and the attention data based on the battery model.

16. The apparatus of claim 12, wherein the data acquirer is further configured to collect the battery data comprising any one or any combination of a voltage signal output from the battery, a current signal output from the battery, and a temperature of the battery.

17. The apparatus of claim 12, wherein the data acquirer is further configured to collect the battery data corresponding to at least a portion of a charging cycle of the battery or at least a portion of a discharging cycle of the battery.

18. The apparatus of claim 12, wherein the processor is further configured to select at least a portion of the input data based on the attention data, and to estimate the battery state information from the selected portion of the input data and the attention data based on the battery model.

19. The apparatus of claim 12, wherein the processor is further configured to generate the input data based on statistical values of the battery data.

20. The apparatus of claim 12, wherein the processor is further configured to generate integrated data by merging the attention data and the input data, and to estimate the battery state information from the integrated data based on the battery model.
